(19) United States
(12) Patent Application Publication
(10) Pub. No.: US 2022/0145494 A1
(43) Pub. Date: May 12, 2022

(54) EXPOSURE OF A SILICON RIBBON TO GAS IN A FURNACE

(71) Applicant: LEADING EDGE CRYSTAL TECHNOLOGIES, INC., Wilmington, MA (US)

(72) Inventors: Alison GREENLEE, Somerville, MA (US); Jesse S. APPEL, South Hamilton, MA (US); Nathan STODDARD, Chalfont, PA (US)

(21) Appl. No.: 17/610,508

(22) PCT Filed: May 12, 2020
(86) PCT No.: PCT/US2020/032437

§ 371 Date: Nov. 11, 2021

Related U.S. Application Data
(60) Provisional application No. 62/847,290, filed on May 13, 2019.

(51) Int. Cl. C30B 31/06; C30B 15/06; C30B 15/00; C30B 29/06; C30B 15/14

(52) U.S. Cl. CPC C30B 31/06; C30B 15/06; C30B 15/14; C30B 29/06; C30B 15/002

(57) ABSTRACT

A system for producing a ribbon from a melt includes a crucible to contain a melt and a cold block. The cold block has a surface that directly faces an exposed surface of the melt. A ribbon is formed on the melt using the cold block. A furnace is operatively connected to the crucible. The ribbon passes through the furnace after removal from the melt. The furnace includes at least one gas jet. The gas jet can dope the ribbon, form a diffusion barrier on the ribbon, and/or passivate the ribbon. Part of the ribbon passes through the furnace while part of the ribbon is being formed in the crucible using the cold block.

### CROSS-REFERENCE TO RELATED APPLICATIONS

This application claims priority to the provisional patent application filed May 13, 2019 and assigned U.S. App. No. 62/847,290, the disclosure of which is hereby incorporated by reference.

### FIELD OF THE DISCLOSURE

This disclosure relates to production of silicon ribbons from a melt.

### BACKGROUND OF THE DISCLOSURE

Silicon wafers or sheets may be used in, for example, the integrated circuit or solar cell industry. Demand for solar cells continues to increase as the demand for renewable energy sources increases. One major cost in the solar cell industry is the wafer or sheet used to make solar cells. Reductions in cost to the wafers or sheets may reduce the cost of solar cells and make this renewable energy technology more prevalent. One promising method that has been investigated to lower the cost of materials for solar cells is the horizontal ribbon growth (HRG) technique where crystalline sheets are pulled horizontally along the surface of a melt. In this method, a portion of a melt surface is cooled sufficiently to locally initiate crystallization with the aid of a seed, which may then be drawn along the melt surface to form a crystalline sheet. The local cooling may be accomplished by providing a device that rapidly removes heat above the region of the melt surface where crystallization is initiated. Under proper conditions, a stable leading edge of the crystalline sheet may be established in this region.

In order to sustain the growth of this faceted leading edge in a steady-state condition with the growth speed matching the pull speed of the monocrystalline sheet, or “ribbon,” intense cooling may be applied by a crystallizer in the crystallization region. This may result in the formation of a monocrystalline sheet whose initial thickness is commensurate with the intensity of the cooling applied. The initial thickness is often on the order of 1-2 mm in the case of silicon ribbon growth. For applications such as forming solar cells from a monocrystalline sheet or ribbon, a target thickness may be on the order of 200 μm or less. This necessitates a reduction in thickness of the initially formed ribbon. This may be accomplished by heating the ribbon over a region of a crucible containing the melt as the ribbon is pulled in a pulling direction. As the ribbon is drawn through the region while the ribbon is in contact with the melt, a given thickness of the ribbon may melt back, thus reducing the ribbon thickness to a target thickness. This melt-back approach is particularly well suited in the so-called Floating Silicon Method (FSM), wherein a silicon sheet is formed on the surface of a silicon melt according to the procedures generally described above.

In traditional ribbon crystal-growth processes, a ribbon travels from the crucible through an inert atmosphere as it cools to a reasonable temperature before exiting the furnace chamber. Separate from the ribbon growth furnace, additional process steps then re-heat and dwell the wafer in specialized gas mixtures to increase material quality (defect engineering and contamination mitigation) and create a desired device architecture. Also, a rapid thermal processing (RTP) process heats up and dwells a wafer at high temperatures to both outgas oxygen and reduce defects.

Producing a ribbon in one machine and then treating this ribbon using a different machine is inefficient and increases manufacturing costs. Using separate machines also increases contamination or generated defects, which affects performance of the solar cell or other device. Improved systems and methods are needed.

### BRIEF SUMMARY OF THE DISCLOSURE

A system is provided in a first embodiment. A system comprises a crucible for containing a melt, a cold block having a cold block surface that directly faces an exposed surface of the melt, a furnace operatively connected to the crucible, and a gas source. The cold block is configured to generate a cold block temperature at the cold block surface that is lower than a melt temperature of the melt at the exposed surface whereby a ribbon is formed on the melt. The ribbon passes through the furnace after removal from the melt such that part of the ribbon passes through the furnace while part of the ribbon is being formed in the crucible using the cold block. The furnace includes at least one gas jet. The gas source is in fluid communication with the gas jet. The gas source contains a gas that dopes the ribbon, forms a surface oxide or other diffusion barrier on the ribbon, passivates the ribbon, and/or changes mechanical properties of the ribbon. The melt and the ribbon can include silicon or other materials.

The system can include a plurality of the gas jets. The gas jets can be arranged in a plurality of zones. Each zone can be separated by a gas curtain. Each zone can provide a different gas.

The gas source can be one of a syngas gas source that includes a mixture of argon and hydrogen, a syngas source that includes a mixture of argon and nitrogen, a POCl₃ gas source, or an oxygen gas source.

The furnace can be configured to have an atmosphere of argon from greater than 0 psi to 20 psi.

The gas jet can direct gas at a top or a bottom of the ribbon.

The gas jet can direct gas at the ribbon at an angle from 0° to 90° relative to a surface of the ribbon.

The furnace can support the ribbon using the gas jet.

A method is provided in a second embodiment. The method comprises providing a melt in a crucible. A ribbon can be formed horizontally on the melt using a cold block having a cold block surface that directly faces an exposed surface of the melt. The ribbon is pulled from the melt at a low angle off the melt surface. The ribbon is transported from the melt to a furnace. Part of the ribbon is transported through the furnace while another part of the ribbon is being formed using the cold block. A gas is directed at the part of the ribbon in the furnace using at least one gas jet. The gas dopes the ribbon, forms a surface oxide or other diffusion barrier on the ribbon, passivates the ribbon and/or changes mechanical properties of the ribbon. The part of the ribbon is transported through an exit of the furnace after the directing while another part of the ribbon is being formed using the cold block. The melt and the ribbon can include silicon or other materials.

The furnace can include a plurality of the gas jets. The gas jets can be arranged in a plurality of zones. Each of the zones can direct a different gas at the ribbon.

In an instance, the gas is a syngas that includes a mixture of argon and hydrogen or includes a mixture of argon and nitrogen. In another instance, the gas is dopant-containing gas. The dopant can be phosphorus. In another instance, the gas is oxygen.

The furnace can be configured to have an atmosphere of argon from greater than 0 psi to 20 psi.

The gas can be directed at a top or a bottom of the ribbon.

The gas can be directed at the ribbon at an angle from 0° to 90° relative to a surface of the ribbon.

The gas can be directed at from greater than 0 m/s to 100 m/s.

### DESCRIPTION OF THE DRAWINGS

For a fuller understanding of the nature and objects of the disclosure, reference should be made to the following detailed description taken in conjunction with the accompanying drawings, in which:

FIG. 1 is a diagram an embodiment of a ribbon exposed to performance-enhancing gases as it travels from the crucible to the furnace exit in accordance with the present disclosure;

FIG. 2 is a flowchart illustrating an embodiment of a method in accordance with the present disclosure;

FIG. 3 is a diagram another embodiment of a ribbon exposed to performance-enhancing gases as it travels from the crucible to the furnace exit in accordance with the present disclosure; and

FIG. 4 is a top view of gas outlets for the gas jets in a zone with the ribbon.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

The present embodiments provide systems to grow a continuous crystalline sheet of semiconductor material, such as silicon, formed from a melt using horizontal growth. In particular, the systems disclosed herein are configured to direct gases at the resulting ribbon. Embodiments disclosed herein include a ribbon growth furnace that exposes the silicon ribbon to gas mixtures before the ribbon cools and/or exits the furnace. This can eliminate the need for additional machines or energy for reheating. This also can provide increased capability or material performance. While some gases are listed in the embodiments disclosed herein, other gases are possible.

Embodiments disclosed herein can reduce the ribbon or resulting wafer's risk of contamination or generating defects. By including a gas exposure step or steps with the ribbon formation, the time the ribbon spends at high temperature can be reduced or minimized. The ribbon is typically most susceptible to contamination or defect generation when at high temperature. For example, metallic species can diffuse quickly into the ribbon at high temperatures, which will reduce the final electrical performance of the resulting wafers. While high temperatures can allow oxygen to outgas from the ribbon, the contamination can be incorporated into the ribbon. Contamination will negatively affect performance of the resulting device. Therefore, the embodiments disclosed herein can be performed in a clean environment with less time spent reheating the ribbon or wafer.

A long or suspended ribbon can eventually sag or suffer gravitational loading to the point where the ribbon material (e.g., silicon) yields. Close to melt temperature, silicon's yield stress is relatively low. Thus, keeping the ribbon hot over a long distance can result in generation of defects, dislocations, or slip. Using embodiments disclosed herein, the ribbon can be mechanically supported at long lengths to prevent defects, dislocations, or slip. The ribbon can be mechanically supported from the bottom and/or top. The temperature of the ribbon also can be cooled in certain areas to provide higher yield stress while supporting the ribbon.

The gas exposure can be configured in a manner that co-mingling or changes to the gas composition of the ribbon in other areas are minimized or prevented. For example, if the ribbon is exposed to phosphine in the furnace to diffuse a junction, the exposure of the melt in the crucible to phosphine can be minimized or prevented. The phosphine can change the doping profile of the melt.

The thermal profile can be tailored either in an inert atmosphere or a specialized atmosphere to mitigate wafer defects. A specialized atmosphere can include a gas mixture meant to generate an effect or to treat the wafer (e.g., change material properties). Doping is an example of changing material properties. Maintaining the ribbon temperature at a given temperature profile (e.g., at a temperature from 700-1414° C. or from 800-1414° C.) can create a profile of both low oxygen and reduced defects in the final ribbon. In an instance, the ribbon can be exposed to a temperature from greater than 1000° C. to the melt temperature of the material in the ribbon, which can provide faster diffusion.

Various performance gases can be used to enhance the quality and/or value of the ribbon as it travels through the furnace. For example, argon, helium, nitrogen, hydrogen, or other inert gases can be used. These gases can minimize contamination by providing non-contact support for the ribbon. These gases can be used during thermal annealing to reduce lifetime-limiting defects, such as at a temperature from 800 to 1414° C. Thus, ribbon or wafer material quality can be maintained.

In another example, a syngas is used. The syngas can include hydrogen with a one or more of argon, helium, nitrogen, or another inert gas. The syngas can increase lifetime by passivating metallic impurities on the ribbon. This can be used to provide ultra-high lifetime wafers (e.g., >1 ms). H₂ can be used for other passivation materials like amorphous silicon or AlO₃.

In another example, POCl₃, phosphine, or another phosphorus-containing gas is used. This gas can increase lifetime because chlorine and/or phosphorus gas can getter wafer impurities. POCl₃ or other phosphorus-containing gases also can diffuse junctions in a solar cell. This can be used to provide ultra-high lifetime wafers (e.g., >1 ms) and can eliminate the need to diffuse junctions outside the furnace. Diffusing a junction can be up to 20% of solar cell manufacturing costs.

While phosphorus-containing gases are disclosed, other dopant-containing gases may be used. For example, dopant-containing gases with arsenic or boron like arsine or boron trifluoride may be used.

Tailored doping profiles also can be provided. In an instance, a junction can be formed at a certain depth in the ribbon. In another instance, different spatial areas on the ribbon are doped differently to build a desired architecture. For example, one strip of the ribbon can be doped p-type and one strip of the ribbon can be doped n-type.

In another example, oxygen is used. Oxygen can minimize contamination by creating an oxide diffusion barrier on the wafer, which can maintain wafer material quality. Oxygen also can increase wafer strength. Thus, oxygen can maintain wafer material quality and enhance wafer strength. Improving wafer strength, affecting stress, or maintaining wafer material quality are examples of changing the mechanical properties of the ribbon.

Specifically for solar cell manufacturing, a high temperature POCl₃ treatment can be used to anneal defects, getter impurities, and diffuse a high-quality junction. The hydrogen from SiNₓ deposition can passivate metallic impurities.

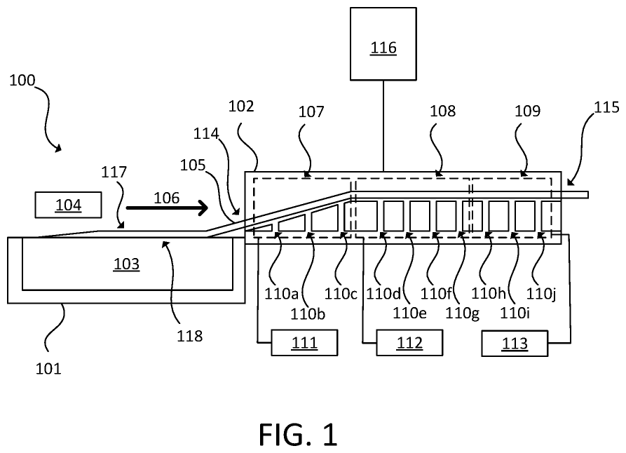

FIG. 1 is a diagram an embodiment of a ribbon exposed to performance-enhancing gases as it travels from the crucible 101 to the furnace exit 115. The system 100 includes a crucible 101 and a furnace 102.

The crucible 101 houses a melt 103. The melt 103 can include, consist of, or consist essentially of silicon, but also can include, consist of, or consist essentially of germanium, silicon and germanium, gallium, gallium nitride, aluminum oxide, or other semiconductor materials.

A ribbon 105 is formed on the surface of the melt 103 using the cold block 104. The ribbon 105 in the crucible 101 is generally made of the same material as the melt 103. The cold block 104 can have a cold block surface that directly faces an exposed surface of the melt 103. The cold block 104 can be configured to generate a cold block temperature at the cold block surface that is lower than a melt temperature of the melt 103 at the exposed surface whereby the ribbon 105 is formed on the melt.

The cold block 104 can generate a cold zone or cold area proximate a surface of the melt 103 that is effective in inducing anisotropic crystallization in a localized area of the surface of the melt 103 while leaving adjacent areas of the melt 103 undisturbed. This facilitates the ability to extract a ribbon 105 of crystalline material.

The cold block 104 can further include or be coupled with a gas jet of cooling gas to assist in formation of the ribbon 105. Thus, the cold block 104 can use convective and/or radiative cooling.

The crucible 101 may be, for example, tungsten, boron nitride, aluminum nitride, molybdenum, graphite, silicon carbide, or quartz. The crucible 101 is configured to contain the melt 105. The melt 105 may be replenished through a feed, such as a feed of solid silicon. A ribbon 105 will be formed on the melt 103. In one instance, the ribbon 105 will at least partly float within the melt 103. While the ribbon 105 is illustrated in FIG. 1 as floating on the melt 103, the ribbon 105 may be at least partially submerged in the melt 103.

For example, the ribbon 105 can be single crystal silicon, polycrystalline silicon, or amorphous silicon.

The ribbon 105 is pulled on the surface of the melt 103 in the direction 106. The ribbon 105 can be separated from the melt 103 at an angle. For example, the ribbon 105 can be pulled from the melt 103 at an angle from greater than 0° to 25° relative to a surface of the melt 103. In another instance, the ribbon 105 is pulled from the melt 103 at 0° relative to a surface of the melt 103. The trajectory of the ribbon 105 can be changed to generally horizontal in or before the furnace 102 after the ribbon 105 is removed from the melt 103.

The furnace 102 is operatively connected to the crucible 101. An entrance 114 to the furnace 102 can be positioned proximate the end of the crucible 101 where the ribbon 105 is pulled from the melt 103. The ribbon 105 passes through the furnace 102 after removal from the melt 103. The furnace 102 includes at least one gas jet 110. In the system 100, ten gas jets 110a-110j are illustrated.

Heaters or insulation may be positioned near or at the entrance 114 of the furnace 102. Additional gas jets 110 or other mechanisms can be used to support the ribbon 105 as it leaves the melt 103 and enters the furnace 102. For example, gas jets 110 can be positioned at the entrance 114 of the furnace 102 to support the ribbon 105.

While the ribbon 105 is illustrated as being transported through the furnace 102 horizontally, the ribbon 105 can be transported through the furnace 102 at an angle relative to the surface of the melt 103. Thus, the ribbon 105 can be transported through the furnace 102 partly or fully at an incline relative to the surface of the melt 103.

Changes to the angle of the ribbon 105 or the orientation of the ribbon 105 may be configured to minimize bending stress in the ribbon.

The ribbon 105 can be pulled through the furnace 102. Part of the ribbon 105 passes through the furnace 102 while part of the ribbon 105 is being formed in the crucible 101 using the cold block 104. Thus, the ribbon 105 can be unbroken between the cold block 104 and an exit 115 for the furnace 102. The formation of the ribbon 105 and the transport of the ribbon 105 through the furnace 102 can be continuous.

External to the furnace 102, a continuous puller can mechanically grab and pull the ribbon 105 out of the furnace 102. The continuous puller can pull the ribbon 105 in a “hand-over-hand” manner. In an instance, the ribbon 105 can be transported through the furnace 102 at a speed from 0.2 mm/s to 20 mm/s.

The gas jets 110 are arranged in one or more zones. For example, from one to ten zones may be included. More than ten zones are possible. In the system 100, three zones 107, 108, and 109 are illustrated, but more or fewer zones are possible. Each of the zones, such as zones 107-109, can provide a different gas to the ribbon 105. Each of the zones also can provide the same gas to the ribbon 105. The zones each can have a different temperature and/or pressure.

A gas source (such as gas sources 111-113) is in fluid communication with a gas jet 110. The gas source contains a gas that can dope the ribbon 105, form a surface oxide or other diffusion barrier on the ribbon 105, passivate the ribbon 105 and/or change mechanical properties of the ribbon 105. Doping the ribbon 105 can alter the bulk electrical properties of the ribbon 105. The surface or bulk of the ribbon can be passivated. Besides a surface oxide, the diffusion barrier can be a nitride (e.g., silicon nitride).

The gas flow to each zone 107-109 can be controlled using valves, which may be operated by a computer subsystem 116. The computer subsystem 116 can use measurements to adjust, for example, the speed the ribbon 105, the temperature in any of the zones 107-109, vacuum or pressure conditions in any of the zones 107-109, or the gas flow rates in any of the zones 107-109. The measurements of the furnace 102 can include temperature, ribbon 105 transport speed, pressure, gas concentration measurements, or other measurements. The measurements can use sensors in the furnace 102.

The computer subsystem 116, other system(s), or other subsystem(s) described herein may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

A processor in the computer subsystem 116 may be configured to perform a number of functions using the output of the furnace 102 or other output. The processor may be configured according to any of the embodiments described herein. The processor also may be configured to perform other functions or additional steps using the output of the furnace 102. For instance, the processor may be configured to send the output to an electronic data storage unit or another storage medium. The processor may be further configured as described herein.

The processor may be communicatively coupled to any of the various components or sub-systems of system 100 in any manner known in the art. Moreover, the processor may be configured to receive and/or acquire data or information from other systems (e.g., test results from inspection of the ribbon, a remote database including ribbon specifications and the like) by a transmission medium that may include wired and/or wireless portions. In this manner, the transmission medium may serve as a data link between the processor and other subsystems of the system 100 or systems external to system 100.

Various steps, functions, and/or operations of system 100 and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random access memory, a magnetic or optical disk, a non-volatile memory, a solid state memory, a magnetic tape, and the like. A carrier medium may include a transmission medium such as a wire, cable, or wireless transmission link. For instance, the various steps described throughout the present disclosure may be carried out by a single processor (or computer subsystem 116) or, alternatively, multiple processors (or multiple computer subsystems 116). Moreover, different sub-systems of the system 100 may include one or more computing or logic systems. Therefore, the above description should not be interpreted as a limitation on the present disclosure but merely an illustration.

Each of the zones 107-109 can be physically separated and/or have gas jets that are isolated from each other. Gas curtains between the zones can provide isolation. Gas flows using particular pressures, gas flows combined with vacuum settings or vacuum pumps, baffles or other geometric structures, and/or the ribbon 105 itself also can be used to isolate the zones 107-109 from each other.

In an instance, the zones 107-109 can be separated by insulation, heat shields, heaters, or other physical mechanisms.

In an instance, the gas jets 110 are fluidically connected to gas sources 111-113. Each of the three gas sources 111-113 contains a different gas. Thus, each zone 107-109 can provide a different gas using the gas jets 110, but each zone 107-109 also can have the same gas. Each of the gas sources 111-113 can be, for example, an argon gas source, a syngas gas source that includes argon and hydrogen, a syngas source that includes argon and nitrogen, a POCl₃ gas source, an oxygen gas source, or other gases. In another example, one of the gas sources a can be a nitrogen gas source, a phosphine gas source, or other dopant-carrying gas source. The type of gas can be selected to achieve specific effect or effects on the ribbon 105. In an instance, the gas is directed at the ribbon 105 while the ribbon is exposed to a temperature greater than 100° C. and less than the melt temperature of the material in the ribbon 105.

The furnace 102 can be configured to have an atmosphere of argon from 0 psi to 20 psi. In an instance, the furnace 102 has an atmosphere of argon that is from greater than 0 psi to 20 psi. For example, a pressure from greater than 0 psi to 1 psi may be used. Low pressures may be used in the furnace 102 to enable laminar flow or reduced turbulent flow. Turbulent flow can increase contamination, but any remaining turbulent flow in the furnace 102 can be compensated for. While argon is disclosed, other inert species can be used in the atmosphere of the ribbon 105 in the furnace 102.

Besides the gases from the gas jets 110, the atmosphere in the furnace 102 can be at a vacuum or near-vacuum level. The ribbon 105 at the entrance and/or exit of the furnace 102 can be combined with a gas curtain or other sealing mechanism to maintain the desired pressure in the furnace 102.

The furnace 102 can include a separate argon source to maintain an atmosphere in the furnace 102. The furnace 102 also can include or be connected with one or more vacuum pumps.

While illustrated as projecting gas from the gas jets 110 at the bottom of the ribbon 105, the gas jets also can direct gas at the top surface of the ribbon 105 opposite the bottom surface. The top surface may be opposite of the melt 103. Thus, one or both of the top and bottom surface of the ribbon 105 can be exposed to the gas in each zone 107-109. The top surface of the ribbon 105 may face the cold block 104 during formation while the opposite bottom surface of the ribbon 105 may be in contact with the melt 103.

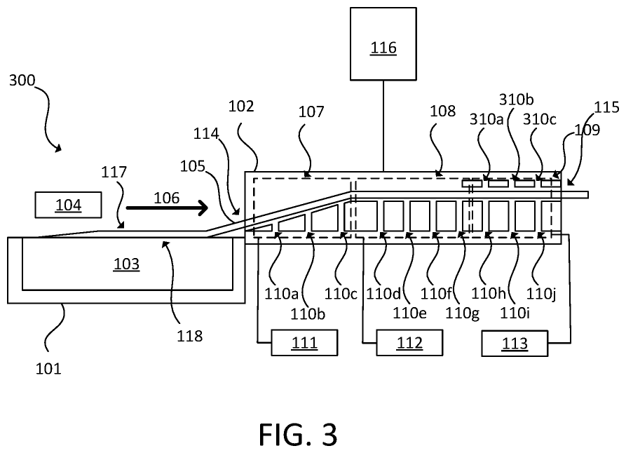

In one particular instance, a gas support is provided to a bottom surface 118 of the ribbon 105 and a gas is directed at a top surface 117 of the ribbon 105 at a point in the furnace 102. The gases can impinge opposite surfaces of the ribbon 105 at the same horizontal point on the ribbon 105. The same gas or different gases may be directed at the top surface 117 and bottom surface 118 of the ribbon 105. For example, the system 300 in FIG. 3 includes gas jets 310a, 310b, and 310c directed at the top surface 117 of the ribbon 105. A Bernoulli gripper can create a suction force on the ribbon 105 to support the ribbon 105 if gas is directed only at the top surface 117 of the ribbon 105.

In another particular instance, a gas is only directed at a bottom surface 118 of the ribbon 105 at a point in the furnace 102. In yet another particular instance, a gas is only directed at a top surface 117 of the ribbon 105 at a point in the furnace 102.

The gas provided in the furnace 102 can support the ribbon 105 similar to an air bearing such that it provides a cushion of gas that the ribbon 105 rests on or is supported by. The ribbon 105 can be held above a surface (e.g., a base or floor) in the furnace 102 using the gas. The gas jets 110 can be used as a gas bearing or separate gas jets from gas jets 110 using an inert gas can be used as the gas bearing. Thus, the ribbon 105 is held between a ceiling and floor of the zones of the furnace 102. While a gas bearing and Bernoulli gripper are disclosed, other mechanical supports may be used with or without a gas bearing and/or Bernoulli gripper.

The ribbon 105 can be supported along its length in the furnace 102 using the gas bearing, Bernoulli gripper, and/or other mechanical supports. In an instance, the gas bearing is capable of supporting the ribbon 105 along its length in the furnace 102 without other supports to the bottom surface 118 of the ribbon 105.

The gas that is used to dope, passivate, or have other effects on the ribbon 105 also can be used to support the ribbon 105. Thus, a dopant gas can be used in the gas bearing to support the ribbon 105. The gas jets 110 can be used to dope, passivate, or have other effects on the ribbon 105 while supporting the ribbon 105. In another instance, separate gas jets can be used to support the ribbon 105 while other gas jets 110 dope, passivate, or have other effects on the ribbon 105.

The gas jets 110 used to support the ribbon 105 as a gas bearing can be directed at an orthogonal angle to the surface of the ribbon 105 or at a non-orthogonal angle to the surface of the ribbon 105,

While illustrated as projecting gas from the gas jets 110 at approximately 90° relative to a surface of the ribbon 105 in FIG. 1 and FIG. 3, the gas from the gas jet can be directed at the surface of the ribbon 105 at an angle from 0° to 90° relative to the surface of the ribbon 105. The angle of the gas from the gas jet can relate to its effects and/or its ability to serve as a gas bearing. The angle of the gas from the gas jet can affect mechanical force imparted to the ribbon. The flow profile of the gas from the gas jet also can affect the rate of diffusion transfer, which can affect doping.

Each zone 107-109 can perform the same or different purpose. For example, each zone 107-109 can dope the ribbon 105, diffuse gas specie to the ribbon 105, create an oxide on the ribbon 105, provide other functions disclosed herein, and/or mechanically support the ribbon 105. The zones 107-109 can be configured to provide a desired ribbon 105 when it leaves the furnace 102.

In an instance, one of the zones 107-109 performs two functions. A mixture of POCl₃ and argon is used to dope the ribbon 105 and minimize contamination of the ribbon 105. Other combinations of the gases disclosed herein are possible.

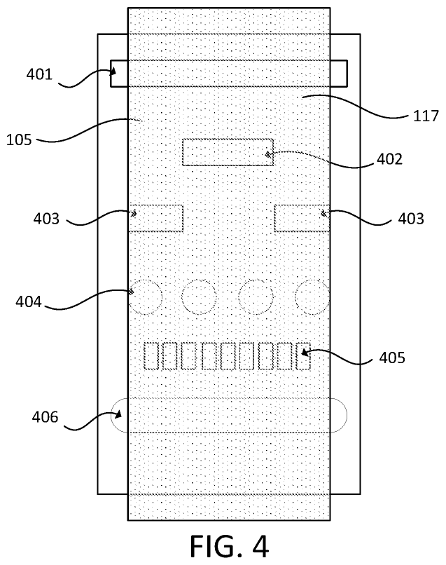

The size, shape, and spacing of the holes used for the gas jets 110 can provide desired performance. For example, the gas jets 110 can be circular, angled, or have slotted openings. The feature size of the gas jets 110 that provides the gas flow can be from 10 μm to 20 cm. FIG. 4 is a top view of gas outlets 401-406 for the gas jets in a zone with the ribbon 105 (which is shaded) positioned over the gas outlets 401-406. The top surface 117 is facing upward and the ribbon 105 is partially transparent for ease of illustration. Other shapes and configurations of gas outlets are possible besides those illustrated in FIG. 4. While multiple different shapes and configurations of gas outlets are illustrated in the zone of FIG. 4, this is done for simplicity. In practice, a zone may only include a single shape or configuration of gas outlets.

Turning back to FIG. 1, the performance of the gas flow injection rate, extraction rate, and corresponding pressure in each of the zones 107-109 can provide desired performance or properties in the ribbon 105. For example, the gas flow injection rate can be from near 0 m/s (e.g., 0.5 m/s) to 100 m/s. The gas flow can be extracted using a vacuum pump or geometric features. The pressure of the gas flow can be from near 0 psi to 100 psi.

Each zone 107-109 can have a length that the ribbon 105 passes through (e.g., along the length of the ribbon 105 or in the direction 106). The length of each zone 107-109 can be from 300 μm to 100 mm.

The temperature range and profile in each zone 107-109 can be configured to provide the desired performance or properties in the ribbon 105. The temperature profile in each zone 107-109 can range from standard temperature and pressure (STP) to the melt temperature of the ribbon 105. For example, the temperature profile of one of the zones 107-109 can be from 800° C. to 1414° C. The temperature in any zone 107-109 can be configured for the function of the gas in the gas jets 110 and/or to minimize thermal stress or defect generation as the ribbon 105 is cooled.

Resistive heaters, insulation, and heat shields may be used to maintain a temperature in each zone 107-109. However, other heating or insulation techniques are possible.

The thermal profile also can be configured to cool the ribbon 105 as it passes from the entrance 114 of the furnace 102 to the exit 115 of the furnace 102. The temperature of the zones 107-109 or the temperature of the gas from the gas jet 110 can be used to cool the ribbon 105. For example, the entrance 114 of the furnace 102 may be at or slightly less than the melt temperature of the material in the ribbon 105 (e.g., 1414° C. for silicon). The exit 115 of the furnace 102 can be approximately room temperature or another temperature less than at the entrance 114. However, the thermal profile can be adjusted for various applications. The thermal profile can be configured to avoid or minimize thermally-generated defects or stress in the ribbon 105.

The effects of the gas from the gas jets 110 can span the entire width and/or length of the ribbon 105 or resulting wafer. The gas jets 110 also can provide smaller local effects on the ribbon 105 or resulting wafer. Thus, the gas jets 110 can expose only part of a width of the ribbon 105 (i.e., a direction going into the page of FIG. 1). For example, global effects along the length of the ribbon 105 or resulting wafer can be passivation or doping. Local effects on the ribbon 105 or resulting wafer can include doping specific device architectures.

The difference in angle of the ribbon 105 when the ribbon 105 exits the furnace 102 relative to the surface of the melt 103 can be from −30° to +60°. FIG. 1 illustrates an angular difference of approximately 0°.

The gas jets 110 can span or cover an entire width of the ribbon 105 with the impinging gas. The gas jets 110 can span or cover less than an entire width of the ribbon 105 with impinging gas. The impinging gas concentration, flow, angle, or other parameters may be non-uniform across the width of the ribbon 105 to address edge effects. At the edges of the width of the ribbon 105, gas may diffuse out more rapidly and/or the edges of the width of the ribbon 105 may be thinner or have a different geometry than a center. These differences can be accommodated. For example, the gas concentration can vary from 100% to a more dilute value (e.g., 0.1%) from the center of the ribbon 105 to the edge of the ribbon 105. In another example, the flow ranges from high to low from the center of the ribbon 105 to the edge of the ribbon 105.

The system 100 can create features in the ribbon 105 or resulting wafer, such as low dopant concentration regions or passivation regions. The gas properties that impinge the ribbon 105 such as concentration, flow, or angle can be configured to provide the desired regions.

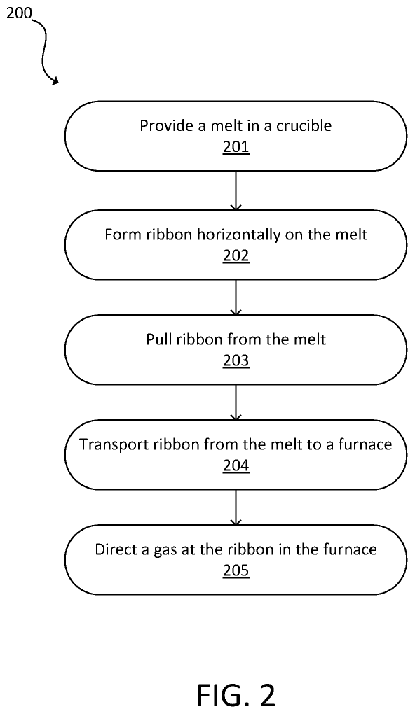

FIG. 2 is a flowchart illustrating an embodiment of a method 200. A melt is provided in a crucible at 201. A ribbon is formed horizontally on the melt using a cold block at 202. The cold block has a cold block surface that directly faces an exposed surface of the melt. The ribbon is pulled and separated from the melt at a low angle off the melt surface at 203. The melt and the ribbon can include, consist of, or can consist essentially of silicon, but other materials are possible.

The ribbon is transported from the melt to a furnace at 204. Part of the ribbon is transported through the furnace while another part of the ribbon is being formed using the cold block. Thus, one end of the ribbon is being formed in the melt while another part of the same ribbon is transported through the furnace. A gas is directed at the ribbon in the furnace using at least one gas jet at 205. The gas can dope the ribbon, form a surface oxide or other diffusion barrier on the ribbon, passivate the ribbon and/or change mechanical properties of the ribbon. The gas can be directed at a top and/or a bottom of the ribbon in each zone. The gas can be directed at the ribbon at an angle from 0° to 90° relative to a surface of the ribbon. The gas can be directed at from 0 m/s to 100 m/s, such as greater than 0 m/s to 100 m/s.

Part of the ribbon is then transported through an exit of the furnace after gas is directed at that part of the ribbon while another part of the ribbon is being formed using the cold block. Thus, part of the ribbon can exit the furnace while one end of the ribbon is being formed in the melt.

The furnace can include a plurality of gas jets. The gas jets can be arranged in a plurality of zones, such as from one to ten zones. The furnace can have an atmosphere of argon from 0 psi to 20 psi, thought other pressures are possible. In an instance, the furnace has an argon pressure from greater than 0 psi to 20 psi.

Each zone can direct a different gas at the ribbon. The gas can be, for example, argon, a syngas that includes argon and hydrogen, a syngas that includes argon and nitrogen, oxygen, or POCl₃, though other gases are possible.

After the ribbon leaves the furnace, the ribbon can be cut into wafers. A laser cutter, a hot press, or a saw, for example, can be used to cut the ribbon into wafers. The resulting wafer may be used for solar cells or other devices.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
a crucible for containing a melt;
a cold block having a cold block surface that directly faces an exposed surface of the melt, the cold block configured to generate a cold block temperature at the cold block surface that is lower than a melt temperature of the melt at the exposed surface whereby a ribbon is formed on the melt;
a furnace operatively connected to the crucible, wherein the ribbon passes through the furnace after removal from the melt such that part of the ribbon passes through the furnace while part of the ribbon is being formed in the crucible using the cold block, wherein the furnace includes at least one gas jet; and
a gas source in fluid communication with the gas jet, wherein the gas source contains a gas that dopes the ribbon, forms a surface oxide or other diffusion barrier on the ribbon, and/or passivates the ribbon.

2. The system of claim 1, wherein the furnace includes a plurality of the gas jets.

3. The system of claim 2, wherein the gas jets are arranged in a plurality of zones separated by a gas curtain, wherein each of the zones provides a different gas.

4. The system of claim 1, wherein the gas source is one of a syngas gas source that includes argon and hydrogen, a syngas source that includes argon and nitrogen, a POCl₃ gas source, or an oxygen gas source.

5. The system of claim 1, wherein the furnace is configured to have an atmosphere of argon from greater than 0 psi to 20 psi.

6. The system of claim 1, wherein the gas jet directs gas at a top or a bottom of the ribbon.

7. The system of claim 1, wherein the gas jet directs gas at the ribbon at an angle from 0° to 90° relative to a surface of the ribbon.

8. The system of claim 1, wherein the furnace supports the ribbon using the gas jet.

9. The system of claim 1, wherein the melt and the ribbon include silicon.

10. A method comprising:
providing a melt in a crucible;
forming a ribbon horizontally on the melt using a cold block having a cold block surface that directly faces an exposed surface of the melt;
pulling the ribbon from the melt at a low angle off the melt surface;
transporting the ribbon from the melt to a furnace;
transporting part of the ribbon through the furnace while another part of the ribbon is being formed using the cold block;
directing a gas at the part of the ribbon in the furnace using at least one gas jet, wherein the gas dopes the ribbon, forms a surface oxide or other diffusion barrier on the ribbon, and/or passivates the ribbon; and
transporting the part of the ribbon through an exit of the furnace after the directing while another part of the ribbon is being formed using the cold block.

11. The method of claim 10, wherein the furnace includes a plurality of the gas jets.

12. The method of claim 11, wherein the gas jets are arranged in a plurality of zones, wherein each of the zones directs a different gas at the ribbon.

13. The method of claim 10, wherein the gas is a syngas that includes argon and hydrogen or that includes argon and nitrogen.

14. The method of claim 10, wherein the gas is dopant-containing gas, wherein the dopant is phosphorus.

15. The method of claim 10, wherein the gas is oxygen.

16. The method of claim 10, wherein the furnace is configured to have an atmosphere of argon from greater than 0 psi to 20 psi.

17. The method of claim 10, wherein the gas is directed at a top or a bottom of the ribbon.

18. The method of claim 10, wherein the gas is directed at the ribbon at an angle from 0° to 90° relative to a surface of the ribbon.

19. The method of claim 10, wherein the gas is directed at from greater than 0 m/s to 100 m/s.

20. The method of claim 10, wherein the melt and the ribbon include silicon.
